(19) United States
(12) Patent Application Publication
(10) Pub. No.: US 2024/0395650 A1
(43) Pub. Date: Nov. 28, 2024

(54) SEMICONDUCTOR PACKAGE

(71) Applicant: Samsung Electronics Co., Ltd., Suwon-si (KR)

(72) Inventor: YOUNGBAE KIM, Suwon-si (KR)

(21) Appl. No.: 18/405,534

(22) Filed: Jan. 5, 2024

(30) Foreign Application Priority Data
May 24, 2023 (KR) 10-2023-0067114

(51) Int. Cl. H01L 23/36; H01L 23/00; H01L 23/31; H01L 25/065; H10B 80/00

(52) U.S. Cl. CPC H01L 23/36; H01L 23/3128; H01L 24/08; H01L 24/32; H01L 25/0652; H01L 25/0657; H10B 80/00; H01L 24/16; H01L 24/73; H01L 2224/08145; H01L 2224/08225; H01L 2224/16145; H01L 2224/32145; H01L 2224/32225; H01L 2224/73204

(57) ABSTRACT

A high bandwidth memory according to an exemplary embodiment may include a buffer die, a memory stack structure disposed on the buffer die and including a stack of a plurality of memory dies, one or more heat dissipation structures disposed on the buffer die, and horizontally adjacent to the memory stack structure, and a molding material disposed on the buffer die so as to encapsulate the memory stack and the one or more heat dissipation structures.

### CROSS-REFERENCE TO RELATED APPLICATION

This application claims priority to and the benefit of Korean Patent Application No. 10-2023-0067114 filed in the Korean Intellectual Property Office on May 24, 2023, the entire contents of which are incorporated herein by reference.

### BACKGROUND OF THE INVENTION

### (a) Field of the Invention

The present disclosure relates to a semiconductor package.

### (b) Description of the Related Art

With the demand for smaller and lighter electronic devices, the semiconductor industry has been seeking to make semiconductor packages to be mounted in electronic devices smaller, lighter, and thinner while making semiconductor packages have higher speed, more functions, and higher capacity. Therefore, there is an increasing need for packaging technologies capable of storing more data and transmitting data at a higher rate, and as such a packaging technology, high bandwidth memory (HBM) capable of achieving a high level of bandwidth by stacking more DRAMs within a unit area of a substrate is well-known.

Since high bandwidth memories are manufactured by stacking the plurality of DRAMs within the unit area of the substrate, they consume more power per unit area, which causes the temperature in the high bandwidth memories to rise. As long as it is difficult or impossible to efficiently release heat which is generated in high bandwidth memories in order to cope with such a rise in temperature of the high bandwidth memories, differences in thermal stress may occur in semiconductor package structures including high bandwidth memories, which may cause warpage of the semiconductor packages and cause the operation speeds of the semiconductor packages to decrease. As a result, the product reliability may decrease.

For this reason, it is important to develop new semiconductor package technologies capable of improving the thermal characteristics of high bandwidth memories by releasing heat which is generated in the high bandwidth memories.

### SUMMARY OF THE INVENTION

The present disclosure describes a high bandwidth memory including one or more heat dissipation structures, which are disposed on a buffer die on which a memory stack structure is disposed, and are disposed side by side with the memory stack structure in order to improve the thermal characteristics of the high bandwidth memory.

A high bandwidth memory according to an exemplary embodiment may include a buffer die, a memory stack disposed on the buffer die and including a stack of a plurality of memory dies, one or more heat dissipation structures disposed on the buffer die, and horizontally adjacent to the memory stack, and a molding material disposed on the buffer die so as to encapsulate the memory stack and the one or more heat dissipation structures.

The one or more heat dissipation structures each may include a dummy die.

The dummy dies may include crystalline silicon.

The high bandwidth memory may further include bonding members between the buffer die and the dummy dies.

The one or more heat dissipation structures each may include heat slug.

The high bandwidth memory may further include thermal interface material (TIM) between the buffer die and the heat slug.

The one or more heat dissipation structures may be horizontally adjacent to respective side surfaces of the memory stack.

The one or more heat dissipation structures may surround one or more side surfaces of the memory stack.

The one or more heat dissipation structures may be horizontally spaced apart from the memory stack.

Upper surfaces of the one or more heat dissipation structures may be exposed to the outside of the high bandwidth memory.

The memory stack may further include an additional heat dissipation structure disposed on top of the memory stack.

The upper surface of the additional heat dissipation structure may be exposed to the outside of the high bandwidth memory.

The high bandwidth memory may further include an interconnection structure between the buffer die and the memory stack.

The interconnection structure may include a plurality of first bonding pads, a first silicon insulating layer that surrounds side surfaces of the plurality of first bonding pads, a plurality of second bonding pads disposed on the plurality of first bonding pads and directly bonded the plurality of the first bonding pads, respectively, and a second silicon insulating layer that surrounds the side surface of the plurality of second bonding pads and is directly bonded to the first silicon insulating layer.

The interconnection structure may include a plurality of micro bumps, and a non-conductive film (NCF) that surrounds the side surfaces of the plurality of micro bumps.

A semiconductor package according to an exemplary embodiment may include an interposer, a logic die on the interposer, and a plurality of high bandwidth memories on the interposer, and each high bandwidth memory of the plurality of high bandwidth memories may include a buffer die, a memory stack disposed on the buffer die and includes a stack of a plurality of memory dies, one or more heat dissipation structures disposed on the buffer die, and horizontally adjacent to the memory stack, and a molding material disposed on the buffer die and encapsulating the memory stack and the one or more heat dissipation structures.

The plurality of high bandwidth memories may be disposed around the logic die, and horizontally adjacent to the logic die.

The interposer may be a silicon interposer.

A semiconductor package according to an exemplary embodiment may include an interposer, a logic die on the interposer, and a high bandwidth memory on the logic die, and the high bandwidth memory may include a buffer die, a memory stack disposed on the buffer die and including a stack of a plurality of memory dies, one or more heat dissipation structures disposed on the buffer die, and horizontally adjacent to the memory stack, and a first molding material disposed on the buffer die and encapsulating the memory stack and the one or more heat dissipation structures.

The semiconductor package may further include a second molding material that is provided on the interposer so as to encapsulate the logic die and the high bandwidth memory.

According to an exemplary embodiment, it is possible to provide a high bandwidth memory including one or more heat dissipation structures, which are disposed on a buffer die on which a memory stack structure is disposed, and are side by side with the memory stack structure in order to improve the thermal characteristics of the high bandwidth memory.

By disposing heat dissipation structures on a buffer die of a high bandwidth memory, it is possible to more easily release heat which is generated in the high bandwidth memory. Therefore, it is possible to improve the thermal characteristics of the high bandwidth memory.

### BRIEF DESCRIPTION OF THE DRAWINGS

FIG. 1 is a cross-sectional view illustrating a high bandwidth memory which includes one or more heat dissipation structures disposed on a buffer die on which a memory stack structure is disposed, and disposed side by side with the memory stack structure, wherein memory dies of the memory stack structure are electrically connected by hybrid bonding, and the memory stack structure and the buffer die are electrically connected by hybrid bonding.

FIG. 2 is a plan view illustrating the upper surface of a high bandwidth memory including heat dissipation structures disposed side by side with a memory stack structure.

FIG. 3 is a plan view illustrating the upper surface of a high bandwidth memory including a heat dissipation structure surrounding a memory stack structure.

FIG. 4 is a cross-sectional view illustrating a high bandwidth memory which includes one or more heat dissipation structures disposed on a buffer die on which a memory stack structure is disposed, and disposed side by side with the memory stack structure, wherein memory dies of the memory stack structure are electrically connected by connecting members, and the memory stack structure and the buffer die are electrically connected by connecting members.

FIG. 5 is a cross-sectional view illustrating a high bandwidth memory which includes one or more heat dissipation structures disposed on a buffer die on which a memory stack structure is disposed, and disposed side by side with the memory stack structure, and includes an additional heat dissipation structure on the memory stack structure, wherein memory dies of the memory stack structure are electrically connected by hybrid bonding, and the memory stack structure and the buffer die are electrically connected by hybrid bonding.

FIG. 6 is a plan view illustrating the upper surface of a high bandwidth memory which includes heat dissipation structures disposed side by side with a memory stack structure and includes an additional heat dissipation structure on the memory stack structure.

FIG. 7 is a plan view illustrating the upper surface of a high bandwidth memory which includes a heat dissipation structure surrounding a memory stack structure and includes an additional heat dissipation structure on the memory stack structure.

FIG. 8 is a cross-sectional view illustrating a 2.5D semiconductor package including high bandwidth memories and a logic die.

FIG. 9 is a plan view illustrating the upper surface of the 2.5D semiconductor package including the high bandwidth memories and the logic die.

FIG. 10 is a cross-sectional view illustrating a 3D semiconductor package including a high bandwidth memory and a logic die.

FIG. 11 is a plan view illustrating the upper surface of the 3D semiconductor package including the high bandwidth memory and the logic die.

### DETAILED DESCRIPTION OF THE EMBODIMENTS

In the following detailed description, only certain exemplary embodiments of the present disclosure have been shown and described, simply by way of illustration. As those skilled in the art would realize, the described embodiments may be modified in various different ways, all without departing from the spirit or scope of the present disclosure.

The drawings and description are to be regarded as illustrative in nature and Like reference numerals designate like elements throughout the not restrictive. specification.

In addition, the size and thickness of each configuration shown in the drawings are arbitrarily shown for understanding and ease of description, but the present disclosure is not limited thereto.

Throughout this specification, when a part is referred to as being “connected” to or “adjacent” to another part, it may be directly connected or adjacent to the other part, or may be connected or adjacent to the other part indirectly with any other elements interposed therebetween. The term “contact” or “in contact with” refers to a direct connection (e.g., touching). In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, in the entire specification, the term “on a plane”, or “in a plan view” refers to when a target part is viewed from above, and the term “on a cross-section”, or “in a cross-sectional view” refers to when the cross-section obtained by cutting a target part vertically is viewed from the side.

Hereinafter, a high bandwidth memory and a semiconductor package according to an exemplary embodiment will be described with reference to the drawings. The term “semiconductor device” may be used herein to generally refer to a high bandwidth memory (or other memory) or to a semiconductor package.

High bandwidth memories (HBM) are high-performance three-dimensional (3D) dynamic random access memories (DRAMs). One memory stack may be formed by vertically stacking memory dies by hybrid bonding or using micro bumps, whereby a high bandwidth memory (HBM) may be manufactured. High bandwidth memories (HBMs) include memory stacks formed by vertically stacking memory dies (e.g., stacking separate memory dies on each other, which dies may each be a portion of a semiconductor wafer), and thus have several memory channels. Therefore, high bandwidth memories can achieve shorter latency and higher bandwidth at the same time as compared to conventional DRAM products, and reduce the total area on a printed circuit board (PCB) to be occupied by individual DRAMs. Accordingly, high bandwidth memories have the advantage of being advantageous for high bandwidth despite their small areas and being capable of reducing power consumption.

However, because high bandwidth memories (HBMs) are manufactured by stacking a plurality of DRAMs within a unit area of a substrate, they consume more power per unit area. Accordingly, the temperature in the high bandwidth memories (HBMs) rises. As long as it is difficult or impossible to efficiently release heat which is generated in high bandwidth memories (HBMs) in order to cope with such a rise in temperature of the high bandwidth memories (HBMs), differences in thermal stress may occur in semiconductor package structures including high bandwidth memories (HBMs), which may cause warpage of the semiconductor packages and cause the operation speeds of the semiconductor packages to decrease. As a result, the product reliability may decrease.

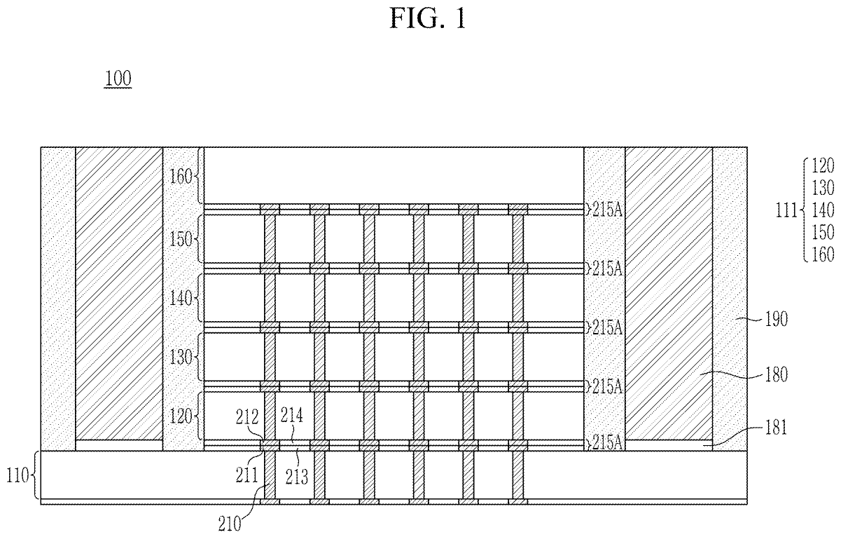

FIG. 1 is a cross-sectional view illustrating a high bandwidth memory 100 which includes one or more heat dissipation structures 180 disposed on a buffer die 110 on which a memory stack structure 111 is disposed, and side by side with the memory stack structure 111, wherein memory dies 120, 130, 140, 150, and 160 of the memory stack structure 111 are connected by hybrid bonding, and the memory stack structure 111 and the buffer die 110 are connected by hybrid bonding.

Referring to FIG. 1, the high bandwidth memory 100 may include the buffer die 110, the memory stack structure 111 including the memory dies 120, 130, 140, 150, and 160, the heat dissipation structures 180, bonding members 181, and a molding material 190.

The buffer die 110 may be disposed at the bottom in the high bandwidth memory 100, and be disposed between the memory stack structure 111 and an external device. When data is exchanged between devices different from each other in data processing speed, the unit in which data is processed, and data usage time, data loss may occur due to the difference in the data processing speed, the difference in the unit in which data is processed, and the difference in the data usage time between the devices. In order to prevent such a loss, the buffer die 110 may be disposed between the memory stack structure 111 and the external device such that it is possible to temporarily store information in the buffer die 110 when data is exchanged between the memory stack structure 111 and the external device. When data is transmitted to the memory dies 120, 130, 140, 150, and 160 or data is received from the memory dies 120, 130, 140, 150, and 160, the buffer die 110 may set up the order of the data and sequentially pass the data. Thus, the buffer die 110 may be a semiconductor device, such as a semiconductor chip, that both physically supports the memory dies 120, 130, 140, 150, and 160, and electrically communicates with the memory dies 120, 130, 140, 150, and 160.

The memory stack structure 111 may be disposed on the buffer die 110. The memory stack structure 111 may include the memory dies 120, 130, 140, 150, and 160 in a stack, and may be described simple as a memory stack or semiconductor memory chip stack. The buffer die 110 may include memory, logic, and redistribution lines connected to the memory stack structure 111. Each of the memory dies 120, 130, 140, 150, and 160 may include a memory cell array for storing data (e.g., including volatile memory cells in the case of DRAM). The memory stack structure 111 may be connected to the buffer die 110 by hybrid bonding. In the memory stack structure 111, the individual memory dies 120, 130, 140, 150, and 160 may be connected by hybrid bonding.

Hybrid bonding may be performed using interconnection structures 215A provided between the buffer die 110 and the memory stack structure 111 or between the memory dies 120, 130, 140, 150, and 160. Hybrid bonding is bonding two devices by a method of fusing the same material of the two devices using the bonding property of the same material. For example, the hybrid bonding may include performing two different types of bonding, for example, bonding two devices by a first type of metal-to-metal bonding and a second type of nonmetal-to-nonmetal bonding. By hybrid bonding, it is possible to form I/O with a fine pitch.

The interconnection structures 215A may include first bonding pads 211, second bonding pads 212, first silicon insulating layers 213, and second silicon insulating layers 214. The first bonding pads 211 may be disposed on the upper surface of the buffer die 110 or the upper surfaces of the memory dies 120, 130, 140, and 150. The second bonding pads 212 may be disposed on the lower surfaces of the memory dies 120, 130, 140, 150, and 160. The first silicon insulating layers 213 may be disposed on the upper surface of the buffer die 110 or on the upper surfaces of the memory dies 120, 130, 140, and 150. The second silicon insulating layers 214 may be disposed on the lower surfaces of the memory dies 120, 130, 140, 150, and 160.

The first bonding pads 211 may be directly bonded to the second bonding pads 212 by metal-to-metal bonding of hybrid bonding. By the metal-to-metal bonding of the hybrid bonding, metallic bonds are formed at the interfaces between the first bonding pads 211 and the second bonding pads 212. In an exemplary embodiment, the first bonding pads 211 and the second bonding pads 212 may include or be copper. In another exemplary embodiment, the first bonding pads 211 and the second bonding pads 212 may include or be another metallic material to which hybrid bonding can be applied.

The first bonding pads 211 and the second bonding pads 212 may be formed of the same material such that after hybrid bonding, the interfaces between the first bonding pads 211 and the second bonding pads 212 disappear. Through the first bonding pads 211 and the second bonding pads 212, the buffer die 110, the memory stack structure 111, and the memory dies 120, 130, 140, 150, and 160 can be electrically connected to each other.

The first silicon insulating layers 213 may be directly bonded to the second silicon insulating layers 214 by nonmetal-to-nonmetal bonding of the hybrid bonding. By the nonmetal-to-nonmetal bonding of the hybrid bonding, covalent bonds are formed at the interfaces between the first silicon insulating layers 213 and the second silicon insulating layers 214.

In an exemplary embodiment, the first silicon insulating layers 213 and the second silicon insulating layers 214 may include or be silicon oxide or TEOS formed oxide. In an exemplary embodiment, the first silicon insulating layers 213 and the second silicon insulating layers 214 may include or be SiO₂. In another exemplary embodiment, the first silicon insulating layers 213 and the second silicon insulating layers 214 may be silicon nitride, silicon oxynitride, or other suitable dielectric materials. In yet another exemplary embodiment, the first silicon insulating layers 213 and the second silicon insulating layers 214 may include or be SiN or SiCN.

The first silicon insulating layers 213 and the second silicon insulating layers 214 may be formed of the same material as each other such that after hybrid bonding, the interfaces between the first silicon insulating layers 213 and the second silicon insulating layers 214 disappear.

Each of the memory dies 120, 130, 140, and 150 may include memory channels and through-silicon vias 210 (generally described as through-substrate vias). The memory die 160 may include memory channels. In an exemplary embodiment, each of the memory dies 120, 130, 140, 150, and 160 may be a DRAM. In other exemplary embodiment, high bandwidth memories 100 including fewer or more memory dies than shown in FIG. 1 are included in the scope of this disclosure.

For electrical coupling between the buffer die 110 and the memory dies 120, 130, 140, 150, and 160, the buffer die 110 and the memory dies 120, 130, 140, and 150 may include the through-silicon vias (TSVs) 210. The uppermost memory die 160 may not include any through-silicon vias 210. The through-silicon vias 210, also described generally as conductive through vias, may be formed so as to be connected to electrodes by forming several thousands of fine holes in each of the dies such that the holes vertically pass through the die, and filling the holes with a conductive material.

In an exemplary embodiment, the holes for the through-silicon vias 210 may be formed by deep etching. In another exemplary embodiment, the holes for the through-silicon vias 210 may be formed by lasers. In an exemplary embodiment, the holes for the through-silicon vias 210 may be filled with a conductive material by electroplating. In an exemplary embodiment, the through-silicon vias 210 may include or be formed of at least one of tungsten, aluminum, copper, and alloys thereof. Further, barrier layers may be formed between the insulating material of the buffer die 110 and the through-silicon vias 210 and between the insulating material of the memory dies 120, 130, 140, 150, and 160 and the through-silicon vias 210. In an exemplary embodiment, the barrier layers may include or be at least one of titanium, tantalum, titanium nitride, tantalum nitride, or alloys thereof. As used herein, a through-silicon via (or through-substrate via) may refer to a filler material, such as tungsten, aluminum, copper, and alloys thereof, combined with a surrounding barrier layer, such as titanium, tantalum, titanium nitride, tantalum nitride, or alloys thereof.

The heat dissipation structures 180 may be disposed on the buffer die 110, and may be side by side with (e.g., adjacent to) the memory stack structure 111. The heat dissipation structures 180 may be spaced apart from the memory stack structure 111 in a horizontal direction. In some embodiments, the side surfaces of the heat dissipation structures 180 may be surrounded by the molding material 190, and the upper surfaces of the heat dissipation structures 180 may be exposed to the outside. For example, a first portion of the molding material 190 may be horizontally between the memory stack structure 111 and the heat dissipation structures 180, and a second portion of the molding material 190 may be horizontally outside the heat dissipation structures 180 to surround the heat dissipation structures 180.

The heat dissipation structures 180, also described as heat dissipation blocks, may include or may be dummy dies manufactured from bare wafers (e.g., pieces of a semiconductor wafer cut into a block shape). In an exemplary embodiment, the heat dissipation structures 180 may include or be crystalline silicon structures. An epoxy molding compound (EMC) which is the main material of the molding material 190 may have a thermal conductivity of about 0.3 W/mK to about 1.0 W/mK. In comparison, the thermal conductivity of silicon is about 83.7 W/mK. Silicon has a thermal conductivity much greater than that of the molding material 190 (e.g., 50 to 500 times the conductivity of the molding material 190). Therefore, as compared to the case where the memory stack structure 111 is encapsulated without the heat dissipation structures 180, in the case where the heat dissipation structures 180 including silicon are formed inside the molding material 190, heat which is generated inside the high bandwidth memory 100 can be effectively released by the heat dissipation structures 180 including silicon.

In some embodiments, the heat dissipation structures 180 may be heat slugs. The heat slugs may also be referred to as heat sinks or heat spreaders. The heat slugs may include or be formed of a metal material having a high thermal conductivity, such as copper, aluminum, etc. Therefore, as compared to the case where the memory stack structure 111 is encapsulated without the heat dissipation structures 180, in the case where the heat dissipation structures 180 including the heat slugs are formed inside the molding material 190, heat which is generated in the high bandwidth memory 100 can be effectively released by the heat dissipation structures 180 including the heat slugs. In some cases, the heat dissipation structures 180, for example when using a heat dissipation material such as metal (e.g., copper or aluminum), can have a thermal conductivity at least 500 and up to 2000 times the heat conductivity of the molding material 190.

In the high bandwidth memory 100, heat may accumulate in the side surfaces of the memory stack structure 111 and the upper surface of the buffer die 110 which are portions in contact with the molding material 190. For this reason, the heat dissipation structures 180 may be located at positions on the upper surface of the buffer die 110 and at a position adjacent to but spaced apart from the side surfaces of the memory stack structure 111, such that they can release heat accumulated in the side surfaces of the memory stack structure 111 and the upper surface of the buffer die 110.

One side (the lower surface) of each heat dissipation structure 180 may physically abut the upper surface of the buffer die 110, and another side (the upper surface) of each heat dissipation structure 180 may be exposed to the outside. Therefore, heat accumulated in the upper surface of the buffer die 110 may be conducted to one side (the lower surface) of each of the heat dissipation structures 180 physically abutting the upper surface of the buffer die 110, and pass through the heat dissipation structures 180, and be released from another side (the upper surface) of each of the heat dissipation structures 180 to the outside. Further, heat accumulated in the side surfaces of the memory stack structure 111 may be conducted to the side surfaces of the heat dissipation structures 180, spaced apart by the molding material 190 from the side surfaces of the memory stack structure, and pass through the heat dissipation structures 180, and be released from another side (the upper surface) of each of the heat dissipation structures 180 to the outside.

In an exemplary embodiment for forming the heat dissipation structures 180, the heat dissipation structures 180 may be attached to the upper surface of the buffer die 110 by the bonding members 181. In an exemplary embodiment in which the heat dissipation structures 180 are silicon structures, the bonding members 181, generally described as a bonding material or bonding layer, may be or include die attach film (DAF), adhesive tape, Ag paste, epoxy resin, or polyimide. The bonding members 181 may therefore be formed of a heat dissipating material or an insulating material, but may have a very small vertical thickness relative to the heat dissipation structures 180 and the buffer die 110 to allow heat to pass therethrough.

In an exemplary embodiment in which the heat dissipation structures 180 are heat slugs, the bonding members 181 may include or be thermal interface material (TIM). Thermal interface material (TIM) includes materials which are inserted between a device which radiates heat (for example, the buffer die 110) and the heat dissipation structures 180, in order to improve thermal coupling. Thermal interface material (TIM) serves to fill air gaps between the contact surfaces of a device which radiates heat and heat dissipation devices, thereby reducing thermal contract resistance. In an exemplary embodiment, the thermal interface material (TIM) may include or be thermal paste, thermal pads, a phase change material (PCM), or a metallic material. In an exemplary embodiment, the thermal interface material (TIM) may include or be grease.

In an exemplary embodiment in which the heat dissipation structures 180 are silicon structures, the heat dissipation structures 180 may be formed by chemical vapor deposition (CVD). In an exemplary embodiment in which the heat dissipation structures 180 are heat slugs, the heat dissipation structures 180 may be formed by physical vapor deposition (PVD).

In other exemplary embodiments for forming the heat dissipation structures 180, after the molding material 190 is formed on the buffer die 110 so as to encapsulate the memory stack structure 111, photoresist application, exposure, development, etching, and deposition processes may be formed such that the heat dissipation structures 180 are formed in the molding material 190. In this case, the heat dissipation structures 180 can be formed without the bonding members 181.

The molding material 190 may be disposed on the buffer die 110 so as to encapsulate the memory stack structure 111 and the heat dissipation structures 180. The molding material 190 may serve to protect and insulate the memory stack structure 111. In an exemplary embodiment, the molding material 190 may be formed of a thermosetting resin such as epoxy resin. In an exemplary embodiment, the molding material 190 may be an epoxy molding compound (EMC). In an exemplary embodiment, the process of forming the molding material 190 may include a compression molding or transfer molding process.

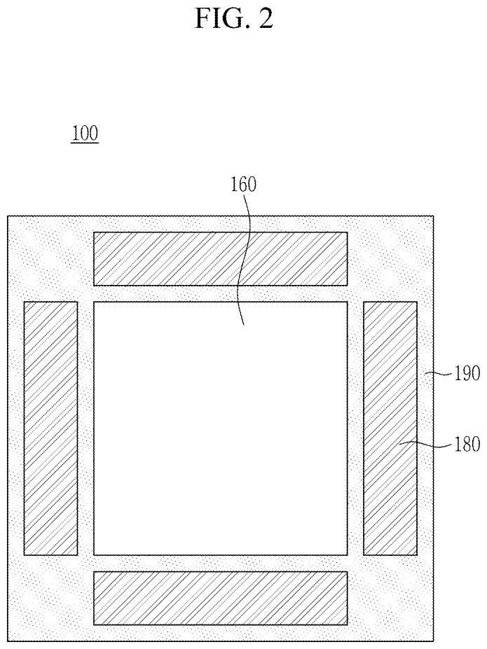

FIG. 2 is a plan view illustrating the upper surface of the high bandwidth memory 100 including the heat dissipation structures 180 disposed side by side with the memory stack structure 111.

Referring to FIG. 2, the heat dissipation structures 180 may be disposed around the uppermost memory die 160 of the memory stack structure 111 (as well as around other memory dies of the memory stack structure) and be spaced apart from the memory die 160 (and the other memory dies of the memory stack structure). According to this disclosure, the heat dissipation structures 180 having a rectangular shape are shown in the drawing; however, the present disclosure is not limited thereto, and the heat dissipation structures may have various shapes. Also, according to this disclosure, it is shown in the drawing that one heat dissipation structure 180 is disposed next to each of the side surfaces of the memory die 160; however, next to one or more of the side surfaces of the memory die 160, a plurality of heat dissipation structures 180 may be disposed, or a heat dissipation structure may be omitted so that no heat dissipation structure is on one or more of the particular side surfaces of the memory die 160. As described herein, a component described as a heat dissipation component (e.g., heat dissipation structure, slug, or chip), is made of a material known to conduct heat (e.g., metal, silicon, etc.). Therefore, a component known as a heat insulator, with low thermal conductivity (e.g., resin), is not a heat dissipation component.

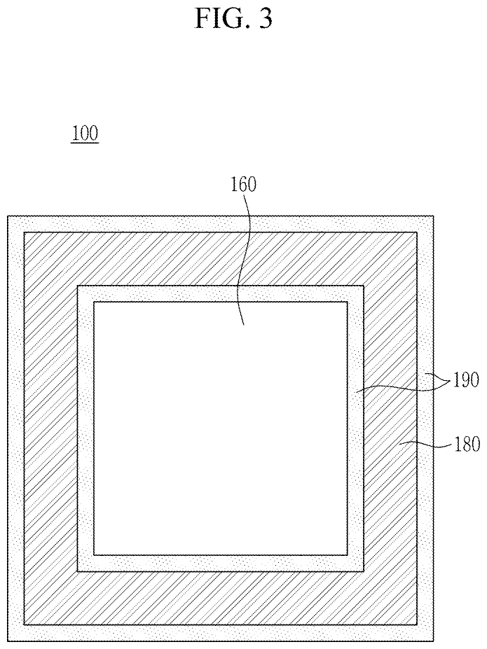

FIG. 3 is a plan view illustrating the upper surface of a high bandwidth memory 100 including a heat dissipation structure 180 surrounding a memory stack structure 111.

Referring to FIG. 3, the heat dissipation structure 180 may be disposed so as to surround the side surfaces of the uppermost memory die 160 (and other memory dies) of the memory stack structure 111 and be apart from the memory die 160 (and other memory dies). According to this disclosure, it is shown in the drawing that one heat dissipation structure 180 surrounds all of the side surfaces of the uppermost memory die 160 of the memory stack structure 111; however, the present disclosure is not limited thereto, and one heat dissipation structure 180 may surround one or more side surfaces of the side surfaces of the uppermost memory die 160 of the memory stack structure 111. Alternatively, a plurality of heat dissipation structures 180 may surround one or more side surfaces of the side surfaces of the uppermost memory die 160 of the memory stack structure 111. A heat dissipation structure may refer to a single piece of continuous, integrated material, which may also be described as a heat dissipation block, or may refer to a group of such heat dissipation blocks which together dissipate heat from a semiconductor chip stack such as a memory stack structure 111.

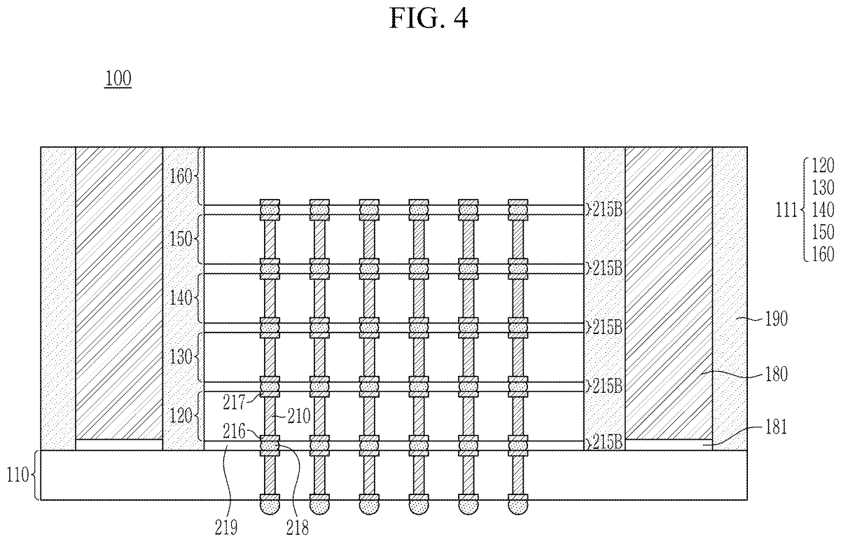

FIG. 4 is a cross-sectional view illustrating a high bandwidth memory which includes one or more heat dissipation structures 180 disposed on a buffer die 110 on which a memory stack structure 111 is disposed, and disposed side by side with the memory stack structure 111 (e.g., in a horizontal direction), wherein memory dies 120, 130, 140, 150, and 160 of the memory stack structure 111 are connected by connecting members 218, and the memory stack structure 111 and the buffer die 110 are connected by connecting members 218.

Referring to FIG. 4, the memory stack structure 111 is connected to the buffer die 110 by interconnection structures 215B (e.g., interconnection layers). In the memory stack structure 111, the memory dies 120, 130, 140, 150, and 160 may be connected by the interconnection structures 215B. The interconnection structures 215B may include the connecting members 218 and insulating members 219. In an exemplary embodiment, the connecting members 218 may include micro bumps, formed of conductive bumps, and may be described as connecting terminals. The insulating members 219, or insulating layers may be disposed between the buffer die 110 and the memory stack structure 111 and between the memory dies 120, 130, 140, 150, and 160 so as to surround the connecting members 218. The insulating members 219 can serve to relieve stress between the buffer die 110 and the memory stack structure 111 and between the memory dies 120, 130, 140, 150, and 160. The insulating members 219 may include or be formed of a non-conductive film (NCF).

Each of the memory dies 120, 130, 140, and 150 may include or be a memory channel, and may include first connecting pads 216, through-silicon vias 210, and second connecting pads 217. In an exemplary embodiment, each of the memory dies 120, 130, 140, 150, and 160 may include or be a DRAM.

The first connecting pads 216 may be conductive pads disposed between the connecting members 218 and the through-silicon vias 210. The first connecting pads 216 may be electrically connect the through-silicon vias 210 to the connecting members 218. The through-silicon vias 210 may be conductive through vias disposed between the first connecting pads 216 and the second connecting pads 217. The through-silicon vias 210 may electrically connect the second connecting pads 217 to the first connecting pads 216. The second connecting pads 217 may be conductive pads disposed between the through-silicon vias 210 and the connecting members 218. The second connecting pads 217 may electrically connect the connecting members 218 to the through-silicon vias 210.

In FIG. 4, the configuration other than the interconnection structures 215B, the first connecting pads 216, and the second connecting pads 217 is the same as the configuration shown in FIG. 1. Therefore, the description of FIG. 1 can be equally applied to the configuration in FIG. 4 other than the interconnection structures 215B, the first connecting pads 216, and the second connecting pads 217.

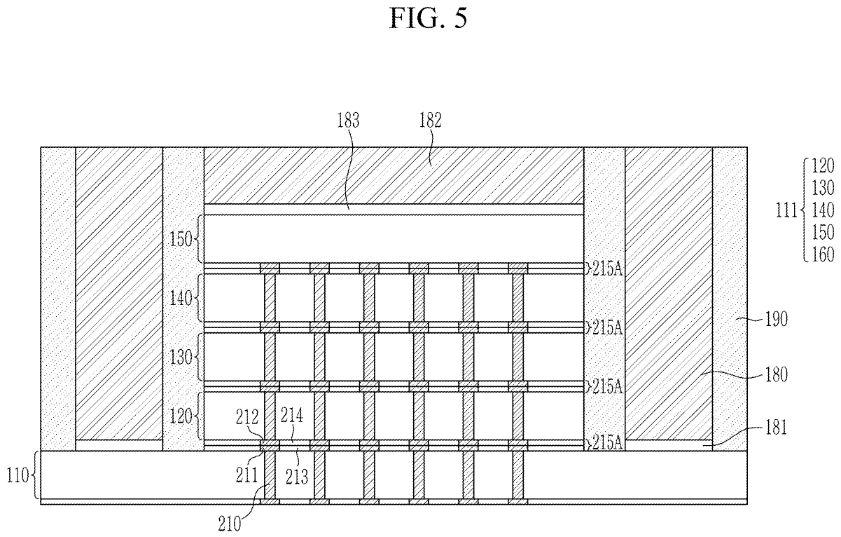

FIG. 5 is a cross-sectional view illustrating a high bandwidth memory 100 which includes one or more heat dissipation structures 180 disposed on a buffer die 110 on which a memory stack structure 111 is disposed, and disposed side by side with the memory stack structure 111, and includes an additional heat dissipation structure 182 on the memory stack structure 111, wherein memory dies 120, 130, 140, 150, and 160 of the memory stack structure 111 are connected by hybrid bonding, and the memory stack structure 111 and the buffer die 110 are connected by hybrid bonding.

Referring to FIG. 5, on the memory stack structure 111, the additional heat dissipation structure 182 and a bonding member 183 may be provided. The side surfaces of the additional heat dissipation structure 182 are surrounded by a molding material 190, and the upper surface of the additional heat dissipation structure 182 may be exposed to the outside (e.g., outside of the HBM). As for the materials, properties, and manufacturing methods of the additional heat dissipation structure 182 and the bonding member 183, the materials, properties, and manufacturing methods of the heat dissipation structures 180 and the bonding members 181 shown in FIG. 1 may be equally applied.

In the high bandwidth memory 100, heat may accumulate in the upper surface of the memory stack structure 111. For this reason, the additional heat dissipation structure 182 may be located on the upper surface of the memory stack structure 111 and release heat accumulated in the upper surface of the memory stack structure 111.

The lower surface of the additional heat dissipation structure 182 may physically abut the upper surface of the memory stack structure 111, and the upper surface of the additional heat dissipation structure 182 may be exposed to the outside and may be coplanar with upper surfaces of the heat dissipation structures 180. Therefore, heat accumulated in the upper surface of the memory stack structure 111 may be conducted to the lower surface of the additional heat dissipation structure 182 physically abutting the upper surface of the memory stack structure 111, and pass through the additional heat dissipation structure 182, and be released from the upper surface of the additional heat dissipation structure 182 to the outside.

In FIG. 5, the configuration except that the additional heat dissipation structure 182 and the bonding member 183 are provided on the memory stack structure 111 is the same as the configuration shown in FIG. 1. Therefore, the description of FIG. 1 can be equally applied to the configuration in FIG. 5 except that the additional heat dissipation structure 182 and the bonding member 183 are provided on the memory stack structure 111.

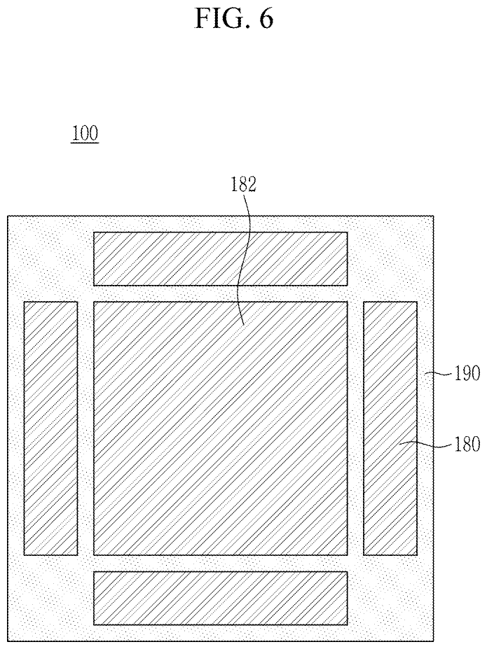

FIG. 6 is a plan view illustrating the upper surface of the high bandwidth memory 100 which includes the heat dissipation structures 180 disposed side by side with the memory stack structure 111 and includes the additional heat dissipation structure 182 on the memory stack structure 111.

Referring to FIG. 6, the heat dissipation structures 180 may be disposed around the additional heat dissipation structure 182 provided on the memory stack structure 111 so as to be apart from the additional heat dissipation structure 182. According to this disclosure, the heat dissipation structures 180 and the additional heat dissipation structure 182 having rectangular shapes are shown in the drawing; however, the present disclosure is not limited thereto, and they may have various shapes. Also, according to this disclosure, it is shown in the drawing that one heat dissipation structure 180 is disposed next to each of the side surfaces of the additional heat dissipation structure 182; however, next to one or more of the side surfaces of the additional heat dissipation structure 182, a plurality of heat dissipation structures 180 may be disposed, or no heat dissipation structure may be disposed.

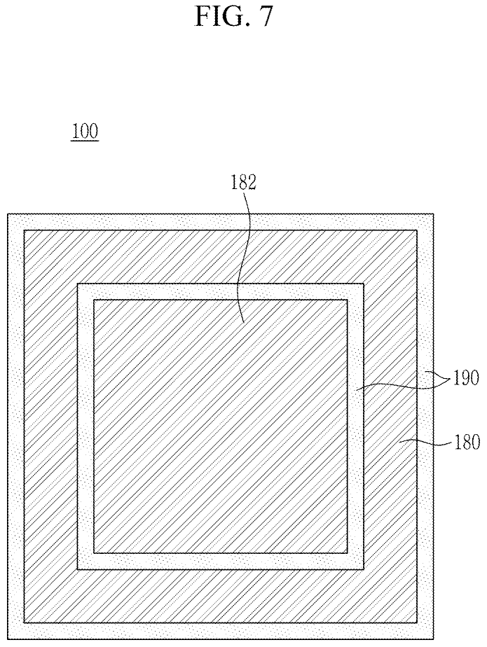

FIG. 7 is a plan view illustrating the upper surface of a high bandwidth memory which includes a heat dissipation structure 180 surrounding a memory stack structure 111 and includes an additional heat dissipation structure 182 on the memory stack structure 111.

Referring to FIG. 7, the heat dissipation structure 180 may be disposed so as to surround the side surfaces of the additional heat dissipation structure 182 on the memory stack structure 111 and be apart from the additional heat dissipation structure 182. According to this disclosure, it is shown in the drawing that one heat dissipation structure 180 surrounds all of the side surfaces of the additional heat dissipation structure 182 provided on the memory stack structure 111; however, the present disclosure is not limited thereto, and one heat dissipation structure 180 may surround one or more side surfaces of the side surfaces of the additional heat dissipation structure 182 provided on the memory stack structure 111. Alternatively, a plurality of heat dissipation structures 180 may surround one or more side surfaces of the side surfaces of the additional heat dissipation structure 182 provided on the memory stack structure 111.

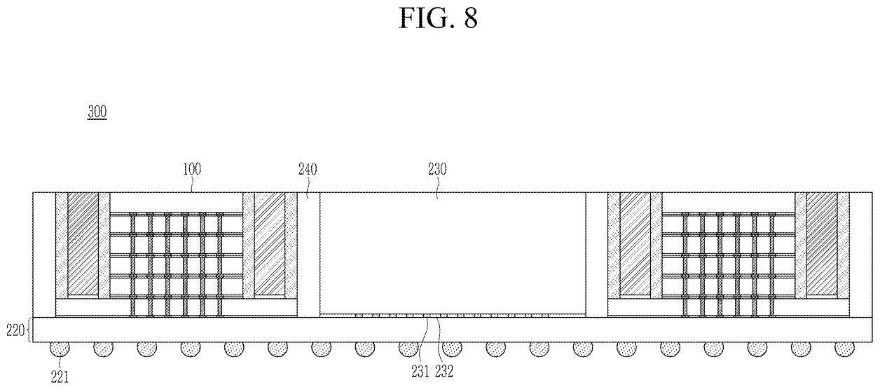

FIG. 8 is a cross-sectional view illustrating a 2.5D semiconductor package 300 including high bandwidth memories 100 as shown in FIG. 1 and a logic die 230. In FIG. 8, only the high bandwidth memories 100 as shown in FIG. 1 are shown; however, in FIG. 8, the high bandwidth memories 100 as shown in FIG. 1 may be replaced with high bandwidth memories 100 as shown in FIG. 4 and FIG. 5.

Referring to FIG. 8, the 2.5D semiconductor package 300 may include an interposer 220, the high bandwidth memories 100, the logic die 230, and a molding material 240.

Below the interposer 220, a substrate may be disposed. On the lower surface of the interposer 220, connecting members 221 may be disposed. In an exemplary embodiment, the interposer 220 may include or be a silicon interposer. The connecting members 221 may be conductive terminals, such as conductive bumps or solder balls.

The high bandwidth memories 100 and the logic die 230 may be disposed on the interposer 220. The high bandwidth memories 100 and the logic die 230 may be connected to the interposer 220 by hybrid bonding. The logic die 230 may include third bonding pads 231 and a third silicon insulating layer 232 for hybrid bonding. Bonding pads and a silicon insulating layer of the interposer 220 which are connected to the third bonding pads 231 and the third silicon insulating layer 232 by hybrid bonding are not shown in the drawing. As for the hybrid bonding, the description of the hybrid bonding related to FIG. 1 may be equally applied.

The logic die 230 may be disposed between the high bandwidth memories 100, and side by side with the high bandwidth memories 100. In an exemplary embodiment, the logic die 230 may include a system on chip (SoC). In an exemplary embodiment, the logic die 230 may include a central processing unit (CPU) or a graphic processing unit (GPU).

The molding material 240 may be disposed on the interposer 220 so as to encapsulate the high bandwidth memories 100 and the logic die 230. The molding material 240 may serve to protect and insulate the high bandwidth memories 100 and the logic die 230. In an exemplary embodiment, the molding material 240 may be formed of a thermosetting resin such as epoxy resin. In an exemplary embodiment, the molding material 240 may be an epoxy molding compound (EMC). In an exemplary embodiment, the process of forming the molding material 240 may include a compression molding or transfer molding process.

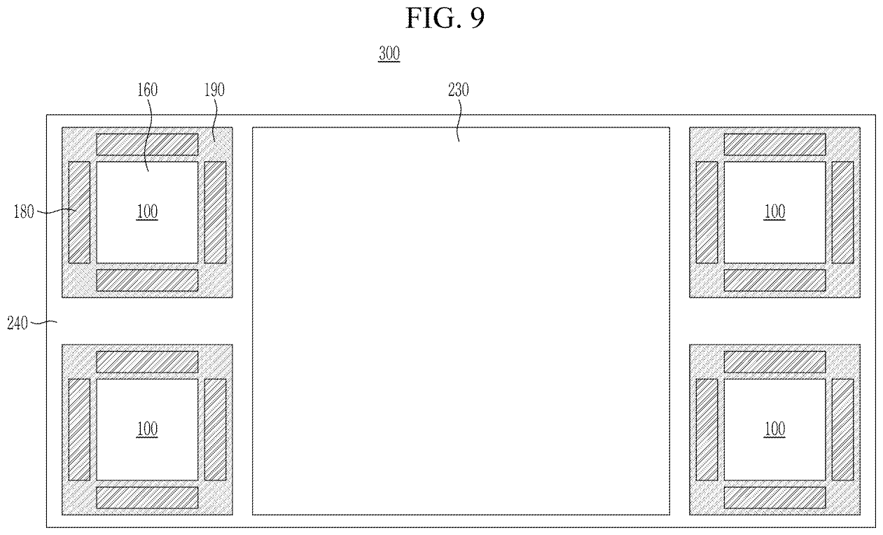

FIG. 9 is a plan view illustrating the upper surface of the 2.5D semiconductor package 300 including the high bandwidth memories 100 and the logic die 230.

Referring to FIG. 9, the high bandwidth memories 100 including heat dissipation structures 180 may be disposed around the logic die 230. Like this, the heat dissipation structures 180 may be disposed on the buffer dies 110 of the high bandwidth memories 100, such that heat which is generated in the high bandwidth memories 100 can be more easily released. As a result, it is possible to improve the thermal characteristics of the 2.5D semiconductor package 300 including the high bandwidth memories 100.

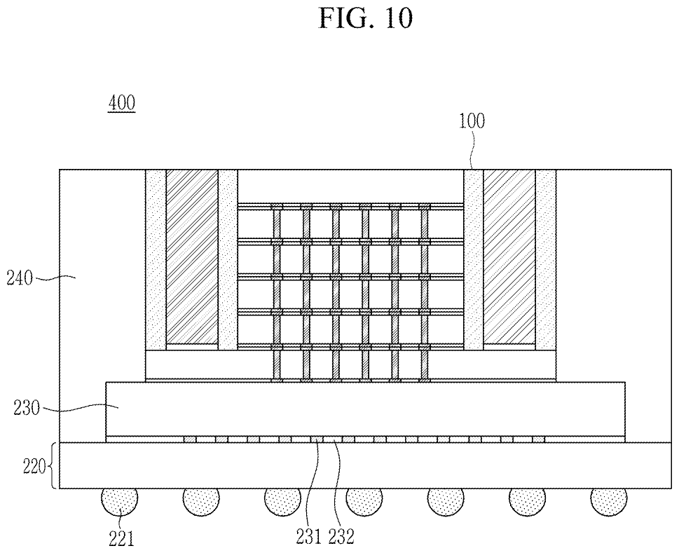

FIG. 10 is a cross-sectional view illustrating a 3D semiconductor package 400 including the high bandwidth memory 100 of FIG. 1 and a logic die 230. In FIG. 10, only the high bandwidth memory 100 of FIG. 1 is shown; however, in FIG. 10, the high bandwidth memory 100 of FIG. 1 may be replaced with the high bandwidth memories 100 of FIG. 4 and FIG. 5.

Referring to FIG. 10, the 3D semiconductor package 400 may include an interposer 220, the high bandwidth memory 100, the logic die 230, and a molding material 240.

Below the interposer 220, a substrate may be disposed. On the lower surface of the interposer 220, connecting members 221 may be disposed. In an exemplary embodiment, the interposer 220 may include or be a silicon interposer.

The logic die 230 may be disposed on the interposer 220. The logic die 230 may be connected to the interposer 220 by hybrid bonding. As for the hybrid bonding, the description of the hybrid bonding related to FIG. 1 may be equally applied. In an exemplary embodiment, the logic die 230 may include a system on chip (SoC). In an exemplary embodiment, the logic die 230 may include a central processing unit (CPU) or a graphic processing unit (GPU).

The high bandwidth memory 100 may be disposed on the logic die 230. The high bandwidth memory 100 may be connected to the logic die 230 by hybrid bonding. As for the hybrid bonding, the description of the hybrid bonding related to FIG. 1 may be equally applied. In FIG. 10, it is shown that one high bandwidth memory 100 is disposed on the logic die 230; however, a plurality of high bandwidth memories 100 may be disposed on the logic die 230.

The molding material 240 may be disposed on the interposer 220 so as to encapsulate the high bandwidth memory 100 and the logic die 230. The molding material 240 may serve to protect and insulate the high bandwidth memory 100 and the logic die 230. In an exemplary embodiment, the molding material 240 may be formed of a thermosetting resin such as epoxy resin. In an exemplary embodiment, the molding material 240 may be an epoxy molding compound (EMC). In an exemplary embodiment, the process of forming the molding material 240 may include a compression molding or transfer molding process.

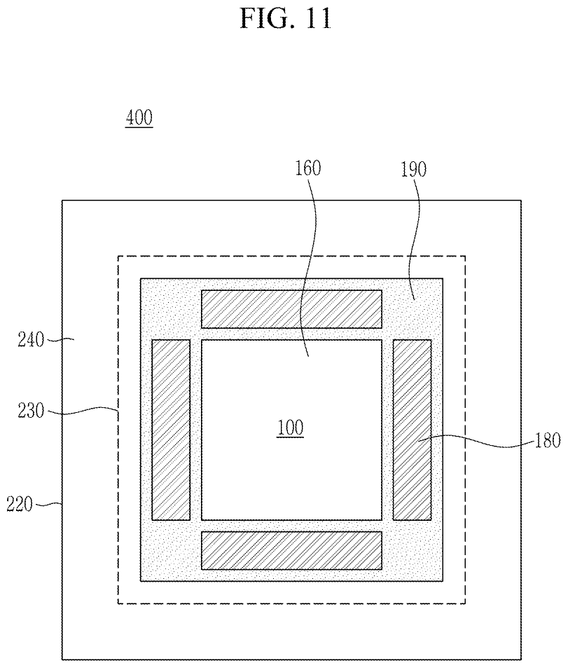

FIG. 11 is a plan view illustrating the upper surface of the 3D semiconductor package 400 including the high bandwidth memory 100 and the logic die 230.

Referring to FIG. 11, on the logic die 230, the high bandwidth memory 100 including the heat dissipation structures 180 may be disposed. Since the logic die 230 is disposed below the molding material 240, the outline of the logic die 230 is shown by a dotted lines. Like this, the heat dissipation structures 180 may be disposed on the buffer die 110 of the high bandwidth memory 100, such that heat which is generated in the high bandwidth memory 100 can be more easily released. As a result, it is possible to improve the thermal characteristics of the 3D semiconductor package 400 including the high bandwidth memory 100.

While this invention has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims.

What is claimed is:

1. A high bandwidth memory comprising:
a buffer die;
a memory stack disposed on the buffer die and including a stack of a plurality of memory dies;
one or more heat dissipation structures disposed on the buffer die, and horizontally adjacent to the memory stack; and
a molding material disposed on the buffer die so as to encapsulate the memory stack and the one or more heat dissipation structures.

2. The high bandwidth memory of claim 1, wherein:
the one or more heat dissipation structures each include dummy dies.

3. The high bandwidth memory of claim 2, wherein:
the dummy dies include crystalline silicon.

4. The high bandwidth memory of claim 3, further comprising:
bonding members between the buffer die and the dummy dies.

5. The high bandwidth memory of claim 1, wherein:
the one or more heat dissipation structures each include heat slug.

6. The high bandwidth memory of claim 5, further comprising:
thermal interface material (TIM) between the buffer die and the heat slug.

7. The high bandwidth memory of claim 1, wherein:
the one or more heat dissipation structures are horizontally adjacent to respective side surfaces of the memory stack.

8. The high bandwidth memory of claim 7, wherein:
the one or more heat dissipation structures are horizontally spaced apart from the memory stack.

9. The high bandwidth memory of claim 1, wherein:
the one or more heat dissipation structures surround one or more side surfaces of the memory stack.

10. The high bandwidth memory of claim 1, wherein:
upper surfaces of the one or more heat dissipation structures are exposed to the outside of the high bandwidth memory.

11. The high bandwidth memory of claim 1, further comprising:
an additional heat dissipation structure disposed on top of the memory stack.

12. The high bandwidth memory of claim 11, wherein:
an upper surface of the additional heat dissipation structure is exposed to the outside of the high bandwidth memory.

13. The high bandwidth memory of claim 1, further comprising:
an interconnection structure between the buffer die and the memory stack.

14. The high bandwidth memory of claim 13, wherein:
the interconnection structure includes:
a plurality of first bonding pads;
a first silicon insulating layer that surrounds side surfaces of the plurality of first bonding pads;
a plurality of second bonding pads disposed on the plurality of first bonding pads and directly bonded to the plurality of first bonding pads, respectively; and
a second silicon insulating layer that surrounds the side surfaces of the plurality of second bonding pads and is directly bonded to the first silicon insulating layer.

15. The high bandwidth memory of claim 1, wherein:
a first portion of the molding material is horizontally between the memory stack and the one or more heat dissipation structures; and
a second portion of the molding material is horizontally outside the one or more heat dissipation structures to surround the one or more heat dissipation structures.

16. A semiconductor package comprising:
an interposer;
a logic die on the interposer; and
a plurality of high bandwidth memories on the interposer, wherein:
each high bandwidth memory of the plurality of high bandwidth memories includes:
a buffer die;
a memory stack disposed on the buffer die and includes a stack of a plurality of memory dies;
one or more heat dissipation structures disposed on the buffer die, and horizontally adjacent to the memory stack; and
a molding material disposed on the buffer die and encapsulating the memory stack and the one or more heat dissipation structures.

17. The semiconductor package of claim 16, wherein:
the plurality of high bandwidth memories are disposed around the logic die, and horizontally adjacent to the logic die.

18. The semiconductor package of claim 16, wherein:
the interposer is a silicon interposer.

19. A semiconductor package comprising:
an interposer;
a logic die on the interposer; and
a high bandwidth memory on the logic die, wherein:
the high bandwidth memory includes:
a buffer die;
a memory stack disposed on the buffer die and including a stack of a plurality of memory dies;
one or more heat dissipation structures disposed on the buffer die, and horizontally adjacent to the memory stack; and
a first molding material disposed on the buffer die and encapsulating the memory stack and the one or more heat dissipation structures.

20. The semiconductor package of claim 19, further comprising:
a second molding material that is provided on the interposer so as to encapsulate the logic die and the high bandwidth memory.
